(19) United States
(12) Patent Application Publication
(10) Pub. No.: US 2026/0129847 A1
(43) Pub. Date: May 7, 2026

(54) SEMICONDUCTOR DEVICE

(71) Applicant: Samsung Electronics Co., Ltd., Suwon-si (KR)

(72) Inventors: HONGSIK SHIN, Suwon-si (KR); Gyeonghwan Noh, Suwon-si (KR); YOUNGSIK SEO, Suwon-si (KR); Seongho Yoo, Suwon-si (KR); JI-HYE LEE, Suwon-si (KR); HYUNCHUL LEE, Suwon-si (KR)

(21) Appl. No.: 19/252,782

(22) Filed: Jun. 27, 2025

(30) Foreign Application Priority Data
Nov. 6, 2024 (KR) 10-2024-0156450

(51) Int. Cl. H10B 12/00

(52) U.S. Cl. CPC H10B 12/50

(57) ABSTRACT

Provided is a semiconductor device including a substrate having an active region formed thereon, a gate stack on the active region, a circuit wiring disposed above the gate stack, and a contact via structure located on a side surface of the gate stack located between the active region and the circuit wiring, wherein the contact via structure includes a gate contact via extending between the circuit wiring and the active region, a first contact insulating film covering a portion of the side surface of the gate contact via and exposing a remaining portion of the side surface, and a second contact insulating film covering a portion of a side surface of the first contact insulating film and exposing a remaining portion of the side surface, and exposing a remaining portion of the side surface of the gate contact via.

### CROSS-REFERENCE TO RELATED APPLICATION

This application claims priority to and the benefit of Korean Patent Application No. 10-2024-0156450 filed in the Korean Intellectual Property Office on Nov. 6, 2024, the entire contents of which are incorporated herein by reference.

### BACKGROUND

The present disclosure relates to a semiconductor device.

Semiconductors are materials having electrical properties between a conductor and an insulator and a semiconductor material may be a material that conducts electricity under certain conditions. Various semiconductor devices such as, for example, memory devices may be manufactured using semiconductor materials. Such semiconductor devices may be used in various electronic devices.

As electronic devices become more miniaturized and highly integrated, there is a need to finely form the patterns that make up semiconductor devices. As the width of these micro-patterns gradually decreases, process difficulty increases, and the defect rate of semiconductor devices may increase.

### SUMMARY

One aspect of the present disclosure provides a semiconductor device capable of improving resistance and performance, preventing short circuit failure with a gate stack and poor contact with an active region, and reducing contact resistance with an active region by preventing a contact via structure from having an enlarged profile or having voids.

A semiconductor device according to one aspect includes a substrate having an active region formed thereon, a gate stack on the active region, a circuit wiring disposed above the gate stack, and a contact via structure located on a side surface of the gate stack in a first direction parallel to an upper surface of the active region and located between the active region and the circuit wiring, wherein the contact via structure includes a gate contact via extending in a third direction perpendicular to the upper surface of the active region between the circuit wiring and the active region, a first contact insulating film covering a portion of the side surface of the gate contact via and exposing a remaining portion of the side surface of the gate contact via, and a second contact insulating film covering a portion of a side surface of the first contact insulating film and exposing a remaining portion of the side surface of the first contact insulating film, and exposing a remaining portion of the side surface of the gate contact via.

A semiconductor device according to another aspect includes a substrate having an active region formed thereon, a gate stack on the active region, a circuit wiring disposed above the gate stack, and a contact via structure located on a side surface of the gate stack in a first direction parallel to an upper surface of the active region and located between the active region and the circuit wiring, wherein the contact via structure has a first portion connected to the circuit wiring, a second portion connected to the active region, a third portion located between the first portion and the second portion, wherein a length of the contact via structure in the first direction has a step between the first portion and the third portion, and has a step between the third portion and the second portion.

A semiconductor device according to another aspect includes a substrate having an active region formed thereon, a circuit wiring formed on the substrate, a first gate stack and a second gate stack located on the active region and spaced apart from each other in a first direction parallel to an upper surface of the active region, a first contact via structure located between the first gate stack and the second gate stack and between the active region and the circuit wiring, and second contact via structures, each located on an outer side of either the first gate stack or the second gate stack in the first direction and located between the active region and the circuit wiring, wherein the first contact via structure includes a gate contact via extending in a third direction perpendicular to the upper surface of the active region to the circuit wiring in the active region, and a first contact insulating film located on a side surface of the gate contact via, and the second contact via structure includes a gate contact via extending in the third direction from the active region to the circuit wiring, a first contact insulating film covering a portion of the side surface of the gate contact via and exposing a remaining portion of the side surface of the gate contact via, and a second contact insulating film covering a portion of a side surface of the first contact insulating film and exposing a remaining portion of the side surface of the first contact insulating film, and exposing a remaining portion of the side surface of the gate contact via.

According to embodiments, provided is semiconductor device capable of improving resistance and performance, preventing short circuit failure with a gate stack and poor contact with an active region, and reducing contact resistance with an active region by preventing a contact via structure from having an enlarged profile or having voids.

### BRIEF DESCRIPTION OF THE DRAWINGS

FIG. 1 is a plan view illustrating a semiconductor device according to an embodiment.

FIG. 2 is a plan view showing a portion of a semiconductor device according to an embodiment.

FIG. 3 is a cross-sectional view taken along lines A-A′, B-B′, and C-C′ of FIG. 2.

FIG. 4 is an enlarged cross-sectional view of portion P of FIG. 3.

FIG. 5 is an enlarged cross-sectional view of portion Q of FIG. 4.

FIG. 6 is a cross-sectional view of a semiconductor device according to an embodiment, corresponding to FIG. 4.

FIGS. 7 to 13 are drawings for explaining a method for manufacturing a semiconductor device according to an embodiment.

### DETAILED DESCRIPTION OF THE EMBODIMENTS

The present disclosure will be described more fully hereinafter with reference to the accompanying drawings, in which embodiments are shown. As those skilled in the art would realize, the described embodiments may be modified in various different ways and embodiments of the invention should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

The drawings and description are to be regarded as illustrative in nature and not restrictive. Like reference numerals designate like elements throughout the specification.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In addition, in the drawings, for better understanding and ease of description, the thickness of some layers and areas is exaggerated.

It will be understood that when an element such as a layer, film, region, or substrate is referred to as being “connected” or “coupled” to or “on” another element, it can be directly connected, coupled to, or on the other element or intervening elements may also be present. In contrast, when an element is referred to as being “directly connected” or “directly coupled” to or “directly on” another element, there are no intervening elements present. The word “on” or “above” means being disposed on or below the object portion, and does not necessarily mean being disposed on the upper side of the object portion based on a gravitational direction.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

In addition, unless explicitly described to the contrary, the word “comprise,” and variations such as “comprises” or “comprising,” will be understood to imply the inclusion of stated elements but not the exclusion of any other elements.

In addition, in this specification, the phrase “on a plane” means having two dimensional planar features such as when viewing a target portion from a direction normal to the plane being referred to (e.g., a vertical view of a horizontal plane), and the phrase “on a cross-section” means viewing a cross-section formed by vertically cutting a target portion from the side. Additionally, unless context clearly indicates otherwise, the plane being referred to is a plane parallel to a reference surface of a substrate, such as an upper or lower surface. The reference surface may also be referred to as a horizontal surface in the context of the semiconductor device.

Additionally, throughout the specification, two directions parallel to and intersecting with the upper surface of the substrate are defined as a first direction DR1 and a second direction DR2, respectively, and a direction perpendicular to the upper surface of the substrate is described as a third direction DR3. For example, the first direction DR1 and the second direction DR2 may be orthogonal to each other.

As used herein, a semiconductor device may refer, for example, to a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices. Semiconductor packages may include a package substrate, one or more semiconductor chips, and an encapsulant formed on the package substrate and covering the semiconductor chips.

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially” may be used herein to emphasize this meaning.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

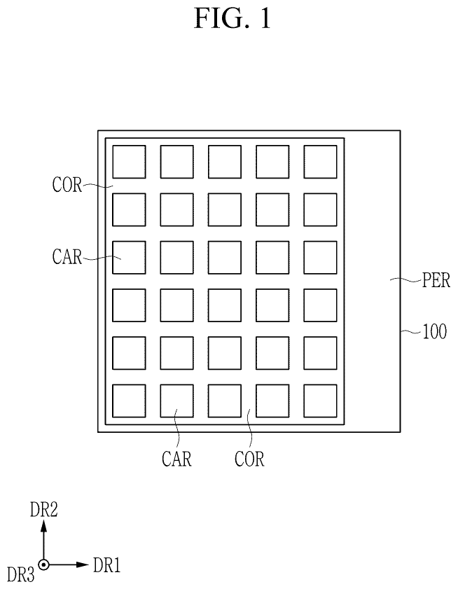

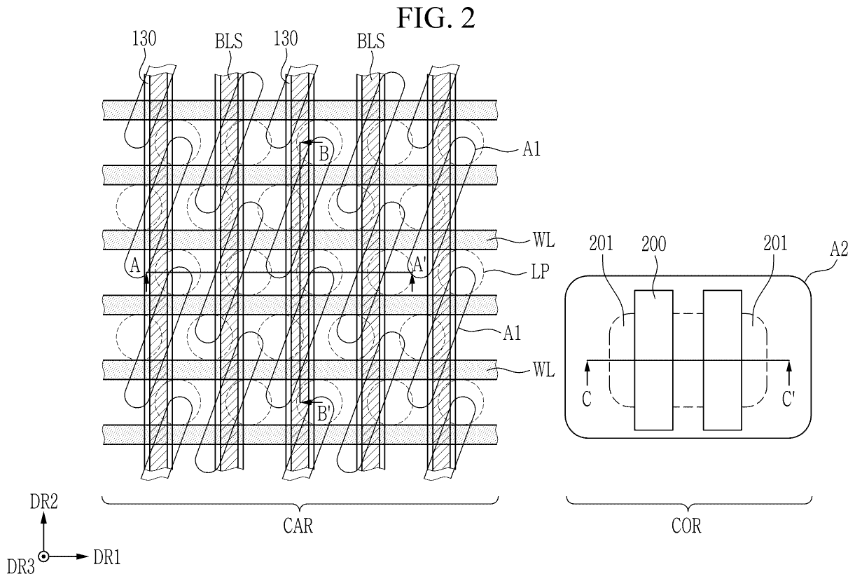

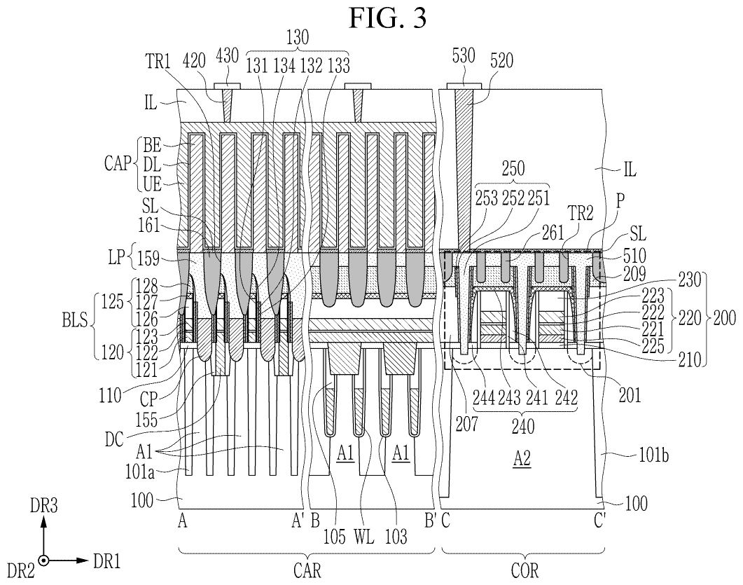

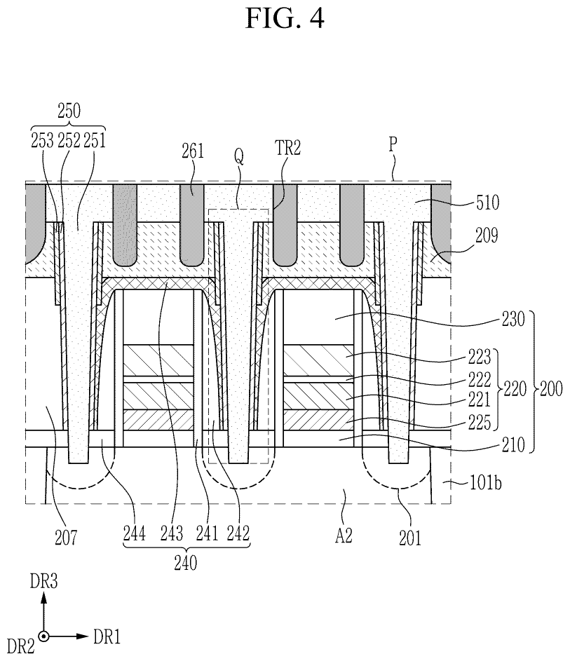

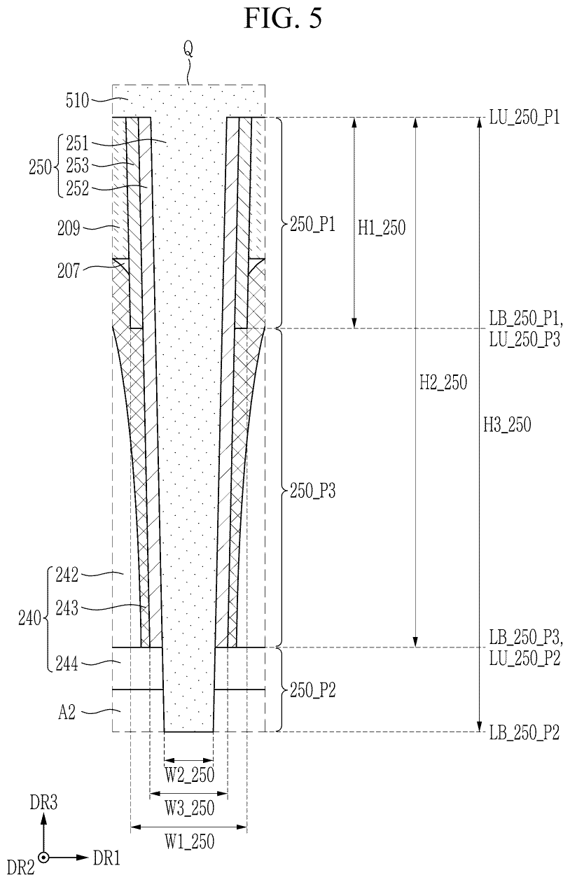

FIG. 1 is a plan view illustrating a semiconductor device according to an embodiment. FIG. 2 is a plan view showing a portion of a semiconductor device according to an embodiment. FIG. 3 is a cross-sectional view taken along lines A-A′, B-B′, and C-C′ of FIG. 2. FIG. 4 is an enlarged cross-sectional view of portion P of FIG. 3. FIG. 5 is an enlarged cross-sectional view of portion Q of FIG. 4.

Referring to FIGS. 1 to 5, a semiconductor device includes a substrate 100 including a cell array region CAR, a core region COR, and a peripheral circuit region PER. A single wafer may include a plurality of semiconductor chips, and FIG. 1 illustrates one semiconductor chip which may be a semiconductor chip from among a plurality of semiconductor chips of a wafer.

For example, the peripheral circuit region PER may be located on a side of the cell array region CAR or the core region COR. The semiconductor chip may have a rectangular shape including two sides parallel in a first direction DR1 and two sides parallel in a second direction DR2, which directions may define a plane, such as the horizontal plane. The second direction DR2 may intersect the first direction DR1. For example, the second direction DR2 may intersect perpendicularly with the first direction DR1. The peripheral circuit region PER may have a bar shape extending along the second direction DR2 on the plane.

On a side of the peripheral circuit region PER, a cell array region CAR and a core region COR may be located. A plurality of cell array regions CARs may be arranged in a matrix form along the first direction DR1 and the second direction DR2. The plurality of cell array regions CARs may be spaced apart from each other, and a core region COR may be located between neighboring cell array regions CAR of the plurality of cell array regions CARs. Each cell array region CAR may be surrounded by a core region COR.

However, the arrangement of the peripheral circuit region PER, cell array region CAR, and core region COR is not limited to this example and may be changed in various ways.

Each of the plurality of cell array regions CARs may include a memory cell. Each cell array region CAR may include a memory cell of a volatile memory element and/or a memory cell of a non-volatile memory element. For example, cell transistors of DRAM (Dynamic Random Access Memory), flash memory, etc. may be located in the cell array region CAR. A cell array region CAR may include a plurality of unit memory cells for storing information. A unit memory cell may include at least one transistor and at least one capacitor.

The core region COR and peripheral circuit region PER may include driving circuits that generate signals for driving memory cells located in the cell array region CAR and wiring that transmits these signals. For example, the core region COR may house a sense amplifier or a write driver. The peripheral circuit region PER may include a row decoder and a column decoder.

The core region COR may include wiring for interconnecting memory cells and driving circuits, as well as contact plugs connecting them (e.g., connecting them to the wiring). The arrangement of these wires and contact plugs may vary depending on location. For example, the arrangement of wires and contact plugs at a location close to the peripheral circuit region PER may be different from the arrangement of wirings and contact plugs at a location far from the peripheral circuit region PER.

A first device isolation film 101a defining first active regions A1 may be located on the cell array region CAR of the substrate 100. The substrate 100 may be a semiconductor substrate and may include a semiconductor material such as silicon, germanium, or silicon-germanium.

The first active regions A1 may be located on the upper portion of the substrate 100. The first active regions A1 may be formed by patterning the upper portion of the substrate 100. The first active regions A1 may have a rectangular (or bar-shaped) shape (e.g., may extend lengthwise in a direction parallel to a base surface of the substrate 100). The first active regions A1 may be two-dimensionally arranged along the first direction DR1 and the second direction DR2. The first active regions A1 may have a longitudinal axis in a diagonal direction with respect to the first direction DR1 and the second direction DR2. Each of the first active regions A1 may reduce in width at locations farther away from the bottom surface of the substrate 100 in cross-section. For example, each of the first active regions A1 may have a width that narrows in the direction perpendicular to the upper surface of the substrate 100 (i.e., the third direction DR3).

Word lines WL may be arranged within the substrate 100. The word lines WL may extend in a first direction DR1 in a planar view and cross the first active regions A1 and the first device isolation film 101a. The word lines WL may be arranged in the second direction DR2 (e.g., may repeat in the second direction with a space between neighboring word lines WL). A gate insulating film 103 may be interposed between the word lines WL and the substrate 100.

Gate recess regions may be formed within the first active regions A1 and the first device isolation film 101a. The gate insulating film 103 may conformally cover the inner walls of the gate recess regions. Word lines WL may fill the lower portions of the gate recess regions. The word lines WL may be spaced apart from the first active regions A1 and the first device isolation film 101a with the gate insulating film 103 therebetween. The upper surfaces of the word lines WL may be located lower than the upper surface of the substrate 100. A gate capping layer 105 may be located on the upper surface of the word lines WL to fill the remainder of the gate recess regions. A level of the upper surface of the gate capping layer 105 may be the same or substantially the same as a level of the upper surface of the substrate 100.

Bit line structures BLS may extend in a second direction DR2 across the first active regions A1 on a horizontal plane. Bit line structures BLS may intersect and be insulated from word lines WL. The bit line structures BLS may include a bit line 120 and a bit line capping pattern 125 on the bit line 120.

The bit line 120 may include a polysilicon pattern 121, a silicide pattern 122, and a metal pattern 123 that are sequentially stacked. A lower insulating film 110 may be interposed between the polysilicon pattern 121 and the substrate 100. A bit line contact pattern DC may be located between the bit line 120 and the first active region A1. The bit line 120 may be electrically connected to the first active region A1 through a bit line contact pattern DC. The lower surface of the bit line contact pattern DC may be located below lower than the upper surface of the substrate 100 and higher than the upper surfaces of the word lines WL. The bit line contact pattern DC may be formed within the substrate 100 and locally placed within a recess region that exposes the upper surface of the first active region A1. The recess region may have an elliptical shape in a planar view (e.g., as viewed normal to the plane), and the width of the recess region in the minor axis direction may be greater than the width of the bit line structures BLS.

A bit line capping pattern 125 may be located on a metal pattern 123 of a bit line 120. The bit line capping pattern 125 may include a first capping pattern 126, a second capping pattern 127, and a third capping pattern 128 that are sequentially stacked.

A bit line contact spacer 155 may fill the remainder of the recess region where the bit line contact pattern DC is formed. For example, the bit line contact spacer 155 may cover opposing sidewalls of the bit line contact pattern DC. As another example, the bit line contact spacer 155 may surround the sides of the bit line contact pattern DC within the recess region. The bit line contact spacer 155 may be formed of an insulating material having etch selectivity with respect to the lower insulating film 110. For example, the bit line contact spacer 155 may include a silicon oxide film, a silicon nitride film, and/or a silicon oxynitride film, and may be formed of a multilayer film. According to embodiments, the upper surface of the bit line contact spacer 155 may be located at the same or substantially the same level as the upper surface of the lower insulating film 110.

Bottom contacts CP may be placed between the sidewalls of the bit line structures BLS. The bottom contacts CP may be arranged along the first direction DR1 on the sidewalls of the bit line structures BLS. Each of the bottom contacts CP may be located, in a planar view, between word lines WL and between bit line structures BLS. Each of the bottom contacts CP may be connected to the substrate 100 between two adjacent bit lines 120 among the bit lines 120. The bottom contact CP may be electrically connected to the first active region A1 of the substrate 100. The bottom contact CP may comprise, for example, doped polysilicon.

The lower end of the bottom contact CP may be located at a level lower than the upper surface of the substrate 100 and may be located at a level higher than the lower surface of the bit line contact pattern DC. The upper surface of the bottom contact CP may be located below the lower surface of the bit line capping pattern 125 of the bit line structure BLS. The bottom contact CP may be insulated from the bit line contact pattern DC by the bit line contact spacer 155.

A landing pad LP may be located on the bottom contact CP. The landing pad LP may be electrically connected to the first active region A1 of the substrate 100 through the bottom contact CP. An upper surface of the landing pad LP may be located above the upper surfaces of the bit line structures BLS, and a lower surface of the landing pad LP may be located below the upper surfaces of the bit line structures BLS. For example, the lower surface of the landing pad LP may be located lower than the upper surface of the metal pattern 123 of the bit line 120. The landing pad LP may include a stacked barrier film (not shown) and a pad metal pattern 159 stacked in sequence. According to embodiments, a contact silicide pattern may be located between the bottom contact CP and the landing pad LP.

A spacer structure 130 may be located between the bit line structures BLS and the bottom contact CP. The spacer structure 130 may extend in the second direction DR2 along the sidewalls of the bit line structures BLS. The spacer structure 130 may include a first spacer 131, a second spacer 132, a third spacer 133, and a fourth spacer 134. The first spacer 131 may be located directly on the sidewall of the bit line structures BLS. The second spacer 132 may be located between the first spacer 131 and the bottom contact CP. A third spacer 133 may be located between the second spacer 132 and the bottom contact CP. The second spacer 132 may be located between the first spacer 131 and the third spacer 133. The first spacer 131 and the third spacer 133 may include an insulating material having etch selectivity with respect to the lower insulating film 110.

The second spacer 132 may include an insulating material having a lower dielectric constant than the first spacer 131 and the third spacer 133. For example, the first spacer 131 and the third spacer 133 may include a silicon nitride film, and the second spacer 132 may include a silicon oxide film. As another example, the second spacer 132 may be an air filled space (e.g., a gap). For example, the second spacer 132 may be an air spacer defined between the sidewalls of the first spacer 131 and the third spacer 133. The fourth spacer 134 may be located on the upper surface of the second spacer 132 and on the side surface of the first spacer 131. The fourth spacer 134 may surround the lower portion of the landing pad LP. The fourth spacer 134 may have a ring shape in a planar view.

An insulating pattern 161 may fill the space between landing pads LPs. The insulating pattern 161 may surround the sidewalls of the landing pads LPs. The insulating pattern 161 may be located within the first trench TR1 between the sidewalls of the landing pads LPs, as illustrated in FIG. 3. The first trench TR1 may be a node isolation trench that electrically isolates each of the landing pads LPs. The landing pads LPs may be spaced apart from each other with a first trench TR1 between them. The first trench TR1 may have an inner side surface defined by surfaces of landing pads LPs, bit line capping patterns 125, and spacer structures 130. For example, the insulating pattern 161 may include silicon nitride.

Capacitors (CAP) may be located on the landing pads LPs. The capacitors CAPs may be electrically connected to the landing pads LPs, respectively. Each of the capacitors CAPs may include a lower electrode BE, an upper electrode UE, and a dielectric layer DL therebetween. Each of the lower electrode BE and the upper electrode UE may include, for example, titanium, tantalum, tungsten, copper, or aluminum.

The lower electrode BE and the upper electrode UE may each include doped silicon, Ru, RuO, Pt, PtO, Ir, IrO, SRO (SrRuO), BSRO ((Ba, Sr)RuO), CRO (CaRuO), BaRuO, La (Sr, Co)O, Ti, TiN, W, WN, Ta, TaN, TiAlN, TiSiN, TaAlN, TaSiN, or a combination thereof. The dielectric layer DL may include, for example, hafnium oxide, hafnium silicon oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

An insulating layer IL and a capacitor contact via 420 that penetrates the insulating layer IL and is connected to the capacitor CAP may be located on the capacitor CAP. The capacitor contact via 420 may be connected to the upper electrode UE of the capacitor CAP.

Cell signal wiring 430 may be located on the insulating layer IL. The cell signal wiring 430 may be located over the capacitor contact via 420 and may be electrically connected to the capacitor contact via 420. The cell signal wiring 430 may be electrically connected to a capacitor CAP through a capacitor contact via 420. The upper electrode UE of the capacitor CAP may receive a predetermined voltage through the cell signal wiring 430.

A gate stack 200 may be arranged on a substrate 100 of a core region COR. The gate stack 200 may extend in a direction parallel to the upper surface of the substrate 100. For example, the gate stack 200 may have a bar shape on a plane such as a horizontal plane. The gate stack 200 may be located on a second active region A2 formed on the upper portion of the substrate 100. The second active region A2 may be a region doped with n-type or p-type impurities and may be defined by a second device isolation film 101b.

Impurity regions 201 may be formed on the upper portion of the substrate 100. The impurity regions 201 may include impurities of a different conductivity type from the impurities doped in the second active region A2. The impurity regions 201 may be a pair of source and drain regions that are electrically connected or separated depending on the voltage applied to the gate stack 200. The impurity regions 201 may be spaced apart from each other with the gate stack 200 between them. Each of the impurity regions 201 may be located adjacent to opposite side surfaces of the gate stack 200. For example, the gate stack 200 and impurity regions may constitute a PMOS transistor, and the impurity regions may be p-type impurity regions. The impurity regions 201 may include, for example, elements such as boron (B), aluminum (Al), gallium (Ga), or indium (In). As another example, the gate stack 200 and the impurity regions 201 may constitute an NMOS transistor, and the impurity regions 201 may be n-type impurity regions. The impurity regions 201 may include, for example, elements such as phosphorus (P), arsenic (As), or antimony (Sb).

The gate stack 200 may include a gate insulating film 210, a gate electrode 220, and a gate capping pattern 230. A gate insulating film 210 may be interposed between the upper surface of the substrate 100 and the gate electrode 220. The gate capping pattern 230 may be located on the upper surface of the gate electrode 220.

The gate insulating film 210 may include a dielectric. According to embodiments, the gate insulating film 210 may include a first dielectric layer and a second dielectric layer on the first dielectric layer. The first dielectric layer may have a lower dielectric constant than the second dielectric layer. The first dielectric layer may include, for example, a silicon oxide film or a silicon oxynitride film. The second dielectric layer may include a high-k material having a higher dielectric constant than the silicon oxide film and the silicon oxynitride film. The second dielectric layer may include an oxide, nitride, silicide, or oxynitride including, for example, hafnium (Hf), aluminum (Al), zirconium (Zr), or lanthanum (La).

The gate electrode 220 may include a work function control layer 225, a first conductive layer 221, a second conductive layer 222, and a third conductive layer 223 that are sequentially stacked. The work function control layer 225 may adjust the threshold voltage of the transistor. For example, the work function control layer 225 may have a thickness greater than a thickness of the gate insulating film 210. The work function control layer 225 may include at least one of a p-type metal film and an n-type metal film. The work function control layer 225 may include a material such as, for example, Ti, Ta, Al, Ni, Co, La, Pd, Nb, Mo, Hf, Ir, Ru, Pt, Yb, Dy, Er, Pd, TiAl, HfSiMo, TiN, WN, TaN, RuN, MoN, TiAlN, TaC, TiC, TaC, or a combination thereof. The work function control layer 225 may further include a material such as, for example, La/TiN, Mg/TiN, Sr/TiN, or a combination thereof.

The first conductive layer 221 may include a doped semiconductor material. The first conductive layer 221 may include, for example, a material such as polysilicon. The first conductive layer 221 may be doped with, for example, a p-type dopant.

The second conductive layer 222 may be located between the first conductive layer 221 and the third conductive layer 223. The second conductive layer 222 may have a thickness less than a thickness of the first conductive layer 221 and the third conductive layer 223. The second conductive layer 222 may include silicide formed at the interface between the first conductive layer 221 and the third conductive layer 223. The second conductive layer 222 may include, for example, a material such as titanium silicide, cobalt silicide, nickel silicide, tungsten silicide, platinum silicide, molybdenum silicide, or a combination thereof.

The third conductive layer 223 may include a metal material. The third conductive layer 223 may include, for example, a material such as W, Ti, Ta, or a combination thereof.

A gate capping pattern 230 may be located on the upper surface of the gate electrode 220. The gate capping pattern 230 is formed to cover the upper surface of the third conductive layer 223 to protect the gate electrode 220. The gate capping pattern 230 may include an insulating material. The gate capping pattern 230 may include, for example, a material such as silicon nitride.

A gate spacer structure 240 may be located on the side surfaces of the gate stack 200. The gate spacer structure 240 may include a first gate spacer 241, a second gate spacer 242, a third gate spacer 243, and a fourth gate spacer 244.

A first gate spacer 241 may be located on the side surface of the gate stack 200 in the first direction D1. The first gate spacer 241 may extend vertically along the side surfaces of the gate stack 200. The first gate spacer 241 may have a lower oxygen element content ratio than the second gate spacer 242. The first gate spacer 241 may have a first dielectric constant having a value in the range of about 6.5 to about 7.5. The first gate spacer 241 may include a first dielectric layer 212 and a material having etch selectivity.

The first gate spacer 241 may include, for example, a material such as silicon nitride.

The upper surface of the first gate spacer 241 may be coplanar with the upper surface of the gate capping pattern 230. The first gate spacer 241 may be directly located on the side surface of the gate electrode 220 and the side surface of the gate capping pattern 230 (e.g., may contact the side surface).

The second gate spacer 242 may be located on the side surface in the first direction D1 of the first gate spacer 241. The second gate spacer 242 may have a width greater than the width of the first gate spacer 241.

A length of the second gate spacer 242 in the first direction D1 may become smaller farther from the upper surface of the substrate 100. For example, the side surface of the second gate spacer 242 in the first direction D1 may be inclined. A width of the second gate spacer 242 may become increasingly smaller as farther away from the upper surface of the substrate 100. The inclined side surface of the second gate spacer 242 may have a convex shape toward the third gate spacer 243. A first interlayer insulating film 207 may be located on a third gate spacer 243 covering an inclined side surface of a second gate spacer 242 in the first direction D1, and the first interlayer insulating film 207 located on a third gate spacer 243 covering an inclined side surface of a second gate spacer 242 in the first direction D1 may be partially overlapped with the second gate spacer 242 and the third gate spacer 243 in the third direction DR3.

The second gate spacer 242 may include, for example, a material such as silicon oxide.

The third gate spacer 243 may be located on the first gate spacer 241 and the second gate spacer 242. The third gate spacer 243 may cover the upper surfaces of the first gate spacer 241 and the second gate spacer 242. The third gate spacer 243 may extend onto the upper surface of the gate stack 200 to cover the upper surface of the first gate spacer 241 and the upper surface of the gate capping pattern 230. The third gate spacer 243 may conformally cover the gate stack 200, the first gate spacer 241, and the second gate spacer 242. In some embodiments, the third gate spacer 243 may extend onto the upper surface of the substrate 100.

The third gate spacer 243 may include, for example, a material such as silicon nitride.

The fourth gate spacer 244 may be located on the second active region A2. The fourth gate spacer 244 may be interposed between the substrate 100 and the first interlayer insulating film 207, and may be for example, interposed between the second active region A2 and the first interlayer insulating film 207. A first interlayer insulating film 207 may be located on the fourth gate spacer 244. The fourth gate spacer 244 may be located next to the gate stack 200 in the first direction DR1. The fourth gate spacer 244 may be located on the lower end portion of the sidewall in the first direction DR1 of the gate stack 200. The fourth gate spacer 244 may be located under the second gate spacer 242 and the third gate spacer 243.

The fourth gate spacer 244 may include, for example, a material such as a silicon oxide film, a silicon nitride film, or a silicon oxynitride film, and may be formed of a multilayer film.

A first interlayer insulating film 207 may be located on the substrate 100. The first interlayer insulating film 207 may cover the sidewalls of the gate spacer structure 240 and may not cover the upper surface of the gate spacer structure 240. The upper surface of the first interlayer insulating film 207 may be coplanar with the upper surface of the third gate spacer 243. The first interlayer insulating film 207 may include an HDP oxide film or a silicon oxide film formed by a FCVD (flowable CVD) method.

A second interlayer insulating film 209 may be located on the first interlayer insulating film 207. The lower surface of the second interlayer insulating film 209 may cover the upper surface of the third gate spacer 243. The second interlayer insulating film 209 may include a material such as silicon nitride.

The core circuit wiring 510 may be located on the second interlayer insulating film 209. The core circuit wiring 510 in the core region COR may be located in the same layer as the pad metal pattern 159 of the landing pad LP in the cell array region CAR. The core circuit wiring 510 may be formed in the same process using the same material as the pad metal pattern 159. The core circuit wiring 510 may be connected to the impurity regions 201 through the contact via structure 250. The core circuit wiring 510 may include, for example, a material such as copper (Cu), tungsten (W), aluminum (Al), tantalum (Ta), or titanium (Ti).

The contact via structure 250 is located between the second active region A2 and the core circuit wiring 510. The contact via structure 250 may be connected to the second active region A2 and the core circuit wiring 510, and the contact via structure 250 may be in contact with the second active region A2 and the core circuit wiring 510. For example, the contact via structure 250 may be electrically connected to the impurity regions 201 of the second active region A2. The contact via structure 250 may electrically connect the second active region A2 and the core circuit wiring 510.

The contact via structure 250 may penetrate through the first interlayer insulating film 207 and the second interlayer insulating film 209 between the second active region A2 and the core circuit wiring 510. The contact via structure 250 may penetrate through the second interlayer insulating film 209 and be connected to a core circuit wiring 510 on the second interlayer insulating film 209. The contact via structure 250 may penetrate through the fourth gate spacer 244 and be connected to the second active region A2 below the fourth gate spacer 244.

The contact via structure 250 may be located on opposite side surfaces of the gate stack 200 in the first direction DR1. The contact via structure 250 may be located spaced apart from the gate stack 200 in the first direction DR1. For example, the gate spacer structure 240 may be located between the contact via structure 250 and the gate stack 200, and, for example, the first gate spacer 241, the second gate spacer 242, and the third gate spacer 243 may be located between the contact via structure 250 and the gate stack 200.

The contact via structure 250 may include a gate contact via 251, a first contact insulating film 252, and a second contact insulating film 253.

The gate contact via 251 may extend in the third direction DR3 from the second active region A2 to the core circuit wiring 510. The gate contact via 251 may be connected to the second active region A2 and the core circuit wiring 510, and the gate contact via 251 may be in contact with the second active region A2 and the core circuit wiring 510. For example, the gate contact via 251 may be electrically connected to the impurity regions 201 of the second active region A2. The gate contact via 251 may electrically connect the second active region A2 and the core circuit wiring 510.

For example, the level in the third direction DR3 at the lower end of the gate contact via 251 may be lower than the level in the third direction DR3 at the upper surface of the second active region A2. For example, the lower end of the gate contact via 251 may penetrate through the upper surface of the second active region A2 and be inserted into the second active region A2 and may be electrically connected to the impurity regions 201 located on the upper surface of the second active region A2. As described below, in the second portion 250_P2 of the contact via structure 250, the first contact insulating film 252 does not cover the side surface of the gate contact via 251, the second contact insulating film 253 does not cover the side surface of the first contact insulating film 252, the second portion 250_P2 of the contact via structure 250 is exposed or open, and the second portion 250_P2 of the contact via structure 250 penetrates through the upper surface of the second active region A2 and is inserted into the second active region A2, so as to be electrically connected to the impurity regions 201 of the second active region A2.

The gate contact via 251 may include, for example, a material such as copper (Cu), tungsten (W), aluminum (Al), tantalum (Ta), titanium (Ti), cobalt (Co), molybdenum (Mo), or a combination thereof. In some embodiments, the gate contact via 251 may be multilayer, and for example, the gate contact via 251 may include a barrier film and a metal pattern that are sequentially stacked.

The first contact insulating film 252 may be located on the side surface of the gate contact via 251.

The first contact insulating film 252 may cover a portion of the side surface of the gate contact via 251 and expose the remaining portion of the side surface without covering it. For example, the first contact insulating film 252 may be located on a side surface of a gate contact via 251 extending in the third direction DR3 between the upper surface of the fourth gate spacer 244 and the lower surface of the core circuit wiring 510. The first contact insulating film 252 may extend in the third direction DR3 from the upper surface of the fourth gate spacer 244 to the lower surface of the core circuit wiring 510. The first contact insulating film 252 may penetrate through the fourth gate spacer 244 and the upper surface of the second active region A2 to expose the side surface of the gate contact via 251 inserted into the second active region A2 without covering it. For example, the first contact insulating film 252 may be located on the side surface of the first portion 250_P1 and the side surface of the third portion 250_P3 of the contact via structure 250 described below, and may not be located on the side surface of the second portion 250_P2 of the contact via structure 250.

A first side surface of the first contact insulating film 252 in the first direction DR1 may be in contact with the gate contact via 251.

A second side surface of the first contact insulating film 252 in the first direction DR1 may be in contact with the second contact insulating film 253. For example, as described below, the second contact insulating film 253 covers the upper portion of the side surface of the first contact insulating film 252 and exposes the lower portion without covering it, so that the upper portion of the side surface of the first contact insulating film 252 may be in contact with the second contact insulating film 253.

Additionally, the second side surface of the first contact insulating film 252 in the first direction DR1 may be in contact with the third gate spacer 243. As described below, when the contact via structure 250 is located between two gate stacks 200, the contact via structure 250 is interposed between the third gate spacers 243 so that the lower portion of the side surface of the first contact insulating film 252 that is exposed and not covered by the second contact insulating film 253 may be in contact with the second contact insulating film 253.

Additionally, the second side surface of the first contact insulating film 252 in the first direction DR1 may be in contact with the first interlayer insulating film 207. As described below, when the contact via structure 250 is located outside rather than between the two gate stacks 200, the contact via structure 250 is interposed between the third gate spacer 243 and the first interlayer insulating film 207, so that the lower portion of the side surface of the first contact insulating film 252 that is exposed and not covered by the second contact insulating film 253 may be in contact with the first interlayer insulating film 207.

The first contact insulating film 252 may include a material such as silicon nitride (SiN), silicon carbon nitride (SiCN), silicon oxycarbon nitride (SiOCN), silicon oxynitride (SiON), silicon oxycarbide (SiOC), or a combination thereof, having a selectivity for silicon oxide (SiO₂).

The second contact insulating film 253 may be located on the side surface of the first contact insulating film 252.

The second contact insulating film 253 may cover a portion of the side surface of the first contact insulating film 252 and expose the remaining portion of the side surface without covering it. For example, the second contact insulating film 253 may be located on the side surface of the first contact insulating film 252 extending in the third direction DR3 between the side surface of the third gate spacer 243 and the lower surface of the core circuit wiring 510. The second contact insulating film 253 may extend from the side surface in the first direction DR1 of the third gate spacer 243 to the lower surface of the core circuit wiring 510 in the third direction DR3.

The second contact insulating film 253 may be interposed between the first interlayer insulating film 207 located on the side surface of the third gate spacer 243 and the side surface of the first contact insulating film 252. The second contact insulating film 253 may be exposed without covering the side surface of the first contact insulating film 252 that is in contact with the side surface of the third gate spacer 243. In addition, the second contact insulating film 253 may penetrate through the fourth gate spacer 244 and the upper surface of the second active region A2 to expose the side surface of the gate contact via 251 inserted into the second active region A2 without covering it. For example, the second contact insulating film 253 may be located on the side surface of the first portion 250_P1 of the contact via structure 250 described later, and may not be located on the side surface of the second portion 250_P2 and the side surface of the third portion 250_P3 of the contact via structure 250. For example, the first contact insulating film 252 may cover from a first point between the upper end and the lower end of the side surface of the gate contact via 251 to the upper end, and the second contact insulating film 253 may cover from a second point between the upper end and the lower end of the side surface of the first contact insulating film 252 to the upper end.

A first side surface of the second contact insulating film 253 in the first direction DR1 may be in contact with the first contact insulating film 252.

A second side surface of the second contact insulating film 253 in the first direction DR1 may be in contact with the second interlayer insulating film 209. As described above, as the second contact insulating film 253 extends in the third direction DR3 from the side surface of the third gate spacer 243 to the lower surface of the core circuit wiring 510, the upper portion of the side surface of the second contact insulating film 253 may be in contact with the second interlayer insulating film 209.

Additionally, the second side surface of the second contact insulating film 253 in the first direction DR1 may be in contact with the first interlayer insulating film 207. For example, as described above, a length of the second gate spacer 242 in the first direction DR1 may become smaller farther from the upper surface of the substrate 100, and as the first interlayer insulating film 207 is located on the third gate spacer 243 covering the inclined side surface of the second gate spacer 242, the second contact insulating film 253 may be in contact with a portion of the side surface of the first interlayer insulating film 207 in the first direction DR1 that is located on the third gate spacer 243 covering the inclined side surface of the second gate spacer 242.

As described above, since the second contact insulating film 253 is interposed between the first interlayer insulating film 207 located on the side surface of the third gate spacer 243 and the side surface of the first contact insulating film 252, the second side surface of the second contact insulating film 253 in the first direction DR1 may be in contact with the side surface of the first interlayer insulating film 207 located on the side surface of the third gate spacer 243.

Additionally, the second side surface of the second contact insulating film 253 in the first direction DR1 may be in contact with the third gate spacer 243. For example, the second contact insulating film 253 may be in contact with a portion of a side surface of the third gate spacer 243 in the first direction DR1. As described below, when the first partial etch for forming the second contact insulating film 253 is performed for a certain period of time and then stopped (time etch), or when the third gate spacer 243 is encountered or when the third gate spacer 243 is partially etched and then stopped, the second side surface of the second contact insulating film 253 in the first direction DR1 may be in contact with the side surface of the third gate spacer 243, and for example, may be located on a recess formed by etching a portion of the side surface of the third gate spacer 243.

For example, the length H3_250 of the gate contact via 251 in the third direction DR3 may be greater than the length H2_250 of the first contact insulating film 252 in the third direction DR3. The length H3_250 of the gate contact via 251 in the third direction DR3 may be greater than the length H2_250 of the first contact insulating film 252 in the third direction DR3 by the length of the second portion 250_P2 in the third direction DR3. Additionally, the length H2_250 of the first contact insulating film 252 in the third direction DR3 may be greater than the length H1_250 of the second contact insulating film 253 in the third direction DR3. The length H2_250 of the first contact insulating film 252 in the third direction DR3 may be greater than the length H1_250 of the second contact insulating film 253 in the third direction DR3 by the length of the third portion 250_P3 in the third direction DR3.

For example, the second contact insulating film 253 may include a material such as silicon nitride (SiN), silicon carbon nitride (SiCN), silicon oxycarbon nitride (SiOCN), silicon oxynitride (SiON), silicon oxycarbide (SiOC), or a combination thereof, which has a selectivity for silicon oxide (SiO₂). For example, the second contact insulating film 253 may include a material such as silicon carbon nitride (SiCN), and the first contact insulating film 252 may include a material such as silicon nitride (SiN). Since silicon nitride (SiN) may prevent the contact via structure 250 from having an enlarged profile compared to silicon carbon nitride (SiCN), the first contact insulating film 252 having a larger contact area with the first interlayer insulating film 207 may include silicon nitride (SiN).

The contact via structure 250 may have a first portion 250_P1, a second portion 250_P2, and a third portion 250_P3.

The third portion 250_P3 may be located on a second portion 250_P2 in the third direction DR3, and a first portion 250_P1 may be located on a third portion 250_P3. For example, the second portion 250_P2, the third portion 250_P3, and the first portion 250_P1 may be sequentially stacked in the third direction DR3. The second portion 250_P2 may be located above the second active region A2, and the first portion 250_P1 may be located below the core circuit wiring 510.

For example, the second portion 250_P2 may extend in the third direction DR3 from within the second active region A2, through the upper surface of the second active region A2, through the fourth gate spacer 244, and to the upper surface of the fourth gate spacer 244. The third portion 250_P3 may extend in the third direction DR3 from the upper surface of the fourth gate spacer 244 to a certain height on the side surface of the third gate spacer 243. The first portion 250_P1 may extend in the third direction DR3 from a certain height on the side surface of the third gate spacer 243 to the lower surface of the core circuit wiring 510. For example, the second portion 250_P2 may extend in the third direction DR3 from within the second active region A2 to the lower end of the first contact insulating film 252, the third portion 250_P3 may extend in the third direction DR3 from the lower end of the first contact insulating film 252 to the lower end of the second contact insulating film 253, and the first portion 250_P1 may extend in the third direction DR3 from the lower end of the second contact insulating film 253 to the upper end of the second contact insulating film 253.

For example, the level LB_250_P2 in the third direction DR3 of the lower end of the second portion 250_P2 may be lower than the level in the third direction DR3 of the upper surface of the second active region A2, and may be the same or substantially the same as the level in the third direction DR3 of the lower end of the gate contact via 251. The level LU_250_P2 in the third direction DR3 of the upper portion of the second portion 250_P2 may be substantially the same or the same as the level in the third direction DR3 of the upper surface of the fourth gate spacer 244, may be the same or substantially the same as the level in the third direction DR3 of the lower portion of the first contact insulating film 252, and may be the same or substantially the same as the level LB_250_P3 in the third direction DR3 of the lower portion of the third portion 250_P3. The level LU_250_P3 in the third direction DR3 of the upper end of the third portion 250_P3 may be the same or substantially the same as the level in the third direction DR3 of the lower end of the second contact insulating film 253, and may be the same or substantially the same as the level LB_250_P1 in the third direction DR3 of the lower end of the first portion 250_P1. The level LU_250_P1 in the third direction DR3 of the upper end of the first portion 250_P1 may be the same or substantially the same as the level in the third direction DR3 of the upper end of the second contact insulating film 253, may be the same or substantially the same as the level in the third direction DR3 of the upper end of the first contact insulating film 252, may be the same or substantially the same as the level in the third direction DR3 of the upper end of the gate contact via 251, and may be the same or substantially the same as the level in the third direction DR3 of the lower surface of the core circuit wiring 510.

The first portion 250_P1 is connected to the core circuit wiring 510. The first portion 250_P1 may include a gate contact via 251, a first contact insulating film 252, and a second contact insulating film 253. For example, in the first portion 250_P1 of the contact via structure 250, the first contact insulating film 252 may cover the side surface of the gate contact via 251, and the second contact insulating film 253 may cover the side surface of the first contact insulating film 252.

The third portion 250_P3 is located between the first portion 250_P1 and the second portion 250_P2. The third portion 250_P3 may include a gate contact via 251 and a first contact insulating film 252. For example, in the third portion 250_P3 of the contact via structure 250, the first contact insulating film 252 may cover the side surface of the gate contact via 251, and the second contact insulating film 253 may expose the first contact insulating film 252 without covering the side surface of the first contact insulating film 252.

The second portion 250_P2 is connected to the second active region A2. The second portion 250_P2 may include a gate contact via 251. For example, in the second portion 250_P2 of the contact via structure 250, the first contact insulating film 252 may expose the gate contact via 251 without covering the side surface of the gate contact via 251, and the second contact insulating film 253 may expose the first contact insulating film 252 without covering the side surface of the first contact insulating film 252. The second portion 250_P2 of the contact via structure 250 penetrates through the upper surface of the second active region A2 and is inserted into the second active region A2, so that it may be directly connected to the impurity regions 201 of the second active region A2. The second portion 250_P2 of the contact via structure 250 may be electrically connected to the impurity regions 201 of the second active region A2.

As described above, the first portion 250_P1 includes a gate contact via 251, a first contact insulating film 252, and a second contact insulating film 253, the third portion 250_P3 includes a gate contact via 251 and a first contact insulating film 252, and the second portion 250_P2 includes a gate contact via 251, and as the second portion 250_P2, the third portion 250_P3, and the first portion 250_P1 are sequentially stacked in the third direction DR3, the length of the contact via structure 250 in the first direction DR1 may have a step between the first portion 250_P1 and the third portion 250_P3, and may have a step between the third portion 250_P3 and the second portion 250_P2. For example, the length of the contact via structure 250 in the first direction DR1 may rapidly decrease between the first portion 250_P1 and the third portion 250_P3, and may rapidly decrease between the third portion 250_P3 and the second portion 250_P2. A degree to which a length of the contact via structure 250 in the first direction DR1 rapidly decreases between the first portion 250_P1 and the third portion 250_P3 may be the same or substantially the same as a thickness of the second contact insulating film 253 in the first direction DR1, and a degree to which a length of the contact via structure 250 abruptly reduces between the third portion 250_P3 and the second portion 250_P2 may be the same or substantially the same as a thickness of the first contact insulating film 252 in the first direction DR1.

For example, the length W1_250 in the first direction DR1 of the lower end of the first portion 250_P1 may be greater than the length W3_250 in the first direction DR1 of the upper end of the third portion 250_P3. The lower end of the first portion 250_P1 and the upper end of the third portion 250_P3 may be connected to each other. Additionally, the length W3_250 in the first direction DR1 of the lower end of the third portion 250_P3 may be greater than the length W2_250 in the first direction DR1 of the upper end of the second portion 250_P2. The lower end of the third portion 250_P3 and the upper end of the second portion 250_P2 may be connected to each other.

As described above, the contact via structure 250 may be adjacent to various film materials. For example, the contact via structure 250 may be adjacent to a third gate spacer 243 including a material such as SiN or the like, and the contact via structure 250 may be adjacent to a first interlayer insulating film 207 including a material such as SiO₂ or the like. In this case, in the process of etching and cleaning the first interlayer insulating film 207 and the third gate spacer 243 to form the contact via structure 250, the first interlayer insulating film 207 including SiO₂ or the like is anisotropically etched so that the contact via structure 250 may have an enlarged profile in a region adjacent to the first interlayer insulating film 207. When the contact via structure 250 has an enlarged profile, voids may occur within the enlarged profile during the process of filling the metal material. If the contact via structure 250 has a void, resistance may increase and performance may deteriorate. If the contact via structure 250 has an enlarged profile, a short defect may occur with the gate stack 200, and a defect in which the gate stack 200 is not in contact with the impurity region 201 of the second active region A2 may occur.

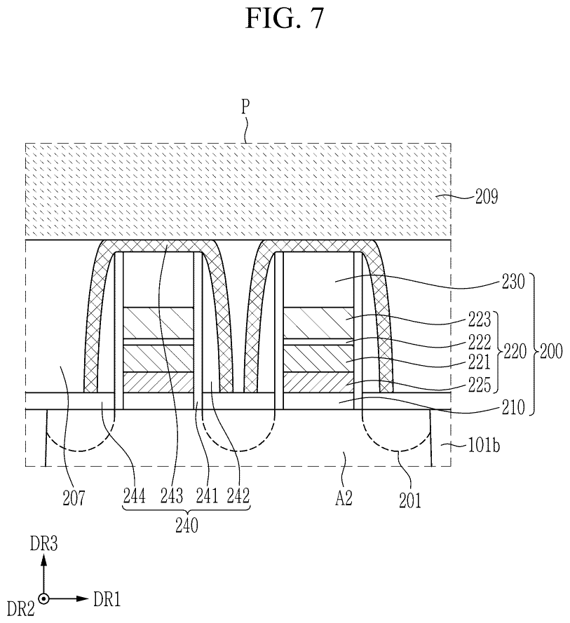

As described later in FIGS. 7 to 13, when a contact via structure 250 is formed through a process of performing a first partial etch, forming a second contact insulating film 253, performing a second partial etch, forming a first contact insulating film 252, performing a third partial etch, and forming a gate contact via 251, the contact via structure 250 may have a structure including a first contact insulating film 252 covering a portion of a side surface of the gate contact via 251 and a second contact insulating film 253 covering a portion of a side surface of the first contact insulating film 252. For example, a portion of the contact via structure 250 may include only one layer of the first contact insulating film 252 and another portion may include two layers including a layer of the first contact insulating film 252 and a layer of the second contact insulating film 253, or may have a double-step structure in which the length in the first direction DR1 of the contact via structure 250 has a step between the first portion 250_P1 and the second portion 250_P2 and a step between the second portion 250_P2 and the third portion 250_P3.

Accordingly, the contact via structure 250 may be prevented from having an enlarged profile or voids, thereby improving resistance and performance, and preventing short circuit defects with the gate stack 200 and contact defects with the second active region A2. The portion where the gate contact via 251 comes into contact with the second active region A2 is exposed without being covered by the first and second contact insulating films 252 and 253, thereby further reducing the contact resistance.

A second trench TR2 may be formed between the core circuit wirings 510. A second trench TR2 may be formed between the sidewalls of the core circuit wirings 510 and may be formed to a predetermined depth from the upper surface of the second interlayer insulating film 209. The lower end of the second trench TR2 may be located at a level higher than the upper surface of the gate capping pattern 230. For example, the second trench TR2 may be located to be vertically overlapped with the gate stack 200 or may be located to be vertically overlapped with the second device isolation film 101b between the gate stacks 200. A wiring insulating pattern 261 may fill the second trench TR2. For example, the wiring insulating pattern 261 may include silicon nitride.

An etch-stop film SL may cover the insulating pattern 161, the wiring insulating pattern 261, and the core circuit wirings 510. An insulating layer IL may be located on the etch-stop film SL. A contact plug 520 may be located to penetrate through the insulating layer IL and the etch-stop film SL and be connected to the core circuit wirings 510. A contact plug 520 located in the core region COR may be located in the same layer as a capacitor contact via 420 located in the cell array region CAR. The contact plug 520 may be formed in the same process using the same material as the capacitor contact via 420.

A core signal wiring 530 may be located on the insulating layer IL. The core signal wiring 530 may be located on the contact plug 520 and may be electrically connected to the contact plug 520. The core signal wiring 530 may be electrically connected to the core circuit wiring 510 through the contact plug 520. The core circuit wiring 510 may receive a predetermined signal through the core signal wiring 530. The core signal wiring 530 located in the core region COR may be located in the same layer as the cell signal wiring 430 located in the cell array region CAR. The core signal wiring 530 may be formed in the same process using the same material as the cell signal wiring 430.

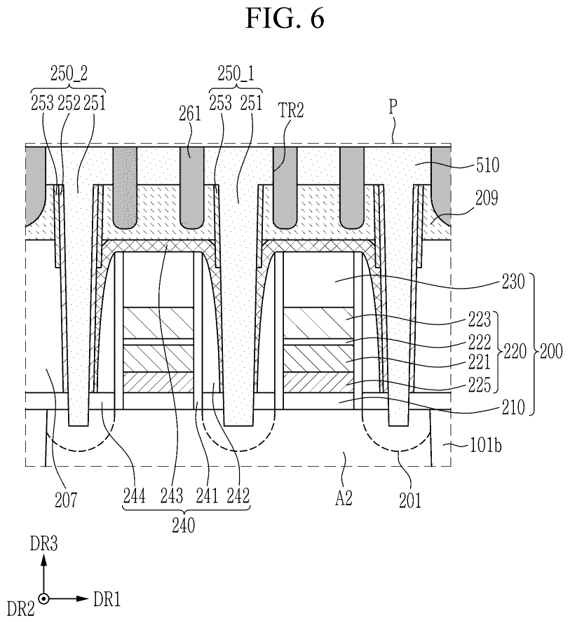

FIG. 6 is a cross-sectional view of a semiconductor device according to an embodiment, corresponding to the view of FIG. 4. For convenience of explanation, a description of elements that are the same as those described previously may be omitted and the description will focus on differences from the description of the embodiments of FIGS. 1 to 5.

Referring to FIGS. 4 and 6, the semiconductor device may include a plurality of gate stacks 200. As an example, the semiconductor device may include first and second gate stacks 200 located spaced apart in a first direction DR1. Additionally, the semiconductor device may include a plurality of contact via structures 250. For example, the semiconductor device may include first contact via structures 250_1 located between first and second gate stacks 200, and second contact via structures 250_2 located on the outer side in the first direction DR1 of the first and second gate stacks 200, respectively.

As the gap between the first and second gate stacks 200 in the first direction DR1 narrows, the first contact via structure 250_1 may be interposed between the third gate spacer 243 covering the first gate stack 200 and the third gate spacer 243 covering the second gate stack 200. For example, the first interlayer insulating film 207 is not interposed between the first contact via structure 250_1 and the third gate spacer 243, and the first contact via structure 250_1 may be in contact with the third gate spacer 243.

For example, the length of the first contact via structure 250_1 in the first direction DR1 may be equal or substantially equal to the distance in the first direction DR1 between the third gate spacer 243 covering the first gate stack 200 and the third gate spacer 243 covering the second gate stack 200. For example, the length of the third portion 250_P3 of the first contact via structure 250_1 in the first direction DR1 may be equal or substantially equal to the distance in the first direction DR1 between the third gate spacer 243 covering the first gate stack 200 and the third gate spacer 243 covering the second gate stack 200.

In FIG. 4, the first contact via structure 250_1 and the second contact via structure 250_2 each have a first portion 250_P1 including a gate contact via 251, a first contact insulating film 252, and a second contact insulating film 253, a third portion 250_P3 including the gate contact via 251 and the first contact insulating film 252, and a second portion 250_P2 including the gate contact via 251, and the first contact insulating film 252 of the third portion 250_P3 of the first contact via structure 250_1 is illustrated as being in contact with the third gate spacer 243 of the first and second gate stacks 200.

For example, in FIG. 4, the third portion 250_P3 of the first contact via structure 250_1 may be interposed between the third gate spacer 243 covering the first gate stack 200 and the third gate spacer 243 covering the second gate stack 200. Additionally, the third portion 250_P3 of the second contact via structure 250_2 may be interposed between the third gate spacer 243 covering the first gate stack 200 or the second gate stack 200 and the first interlayer insulating film 207.

In FIG. 6, the first contact via structure 250_1 does not include the first contact insulating film 252 and does not have the third portion 250_P3. For example, the first contact via structure 250_1 may include a gate contact via 251 extending in a third direction DR3 from the second active region A2 to the core circuit wiring 510, and a first contact insulating film 252 located on a side surface of the gate contact via 251. Additionally, the first contact via structure 250_1 may have a first portion 250_P1 including a gate contact via 251 and a first contact insulating film 252, and a second portion 250_P2 including the gate contact via 251.

As described above, as the gap between the first and second gate stacks 200 in the first direction DR1 becomes narrower, the first contact via structure 250_1 may be in contact with the third gate spacer 243, and since the first interlayer insulating film 207 is not interposed between the first contact via structure 250_1 and the third gate spacer 243, the first contact via structure 250_1 may be prevented from having an enlarged profile even when it does not include the first contact insulating film 252.

The second contact insulating film 253 of the first contact via structure 250_1 may be located on the side of the gate contact via 251. The second contact insulating film 253 may cover a portion of the side surface of the gate contact via 251 and expose the remaining portion of the side surface without covering it. For example, the second contact insulating film 253 may be located on the side surface of a gate contact via 251 extending in the third direction DR3 between the side surface of the third gate spacer 243 and the lower surface of the core circuit wiring 510. The second contact insulating film 253 may extend from the side surface in the first direction DR1 of the third gate spacer 243 to the lower surface of the core circuit wiring 510 in the third direction DR3.

The second contact insulating film 253 of the first contact via structure 250_1 may be interposed between the first interlayer insulating film 207 located on the side surface of the third gate spacer 243 and the side surface of the gate contact via 251. The second contact insulating film 253 may expose the side surface of the gate contact via 251 that is in contact with the side surface of the third gate spacer 243 without covering it. In addition, the second contact insulating film 253 may penetrate through the fourth gate spacer 244 and the upper surface of the second active region A2 to expose the side surface of the gate contact via 251 inserted into the second active region A2 without covering it. For example, the second contact insulating film 253 of the first contact via structure 250_1 may be located on the side surface of the first portion 250_P1 of the contact via structure 250 and may not be located on the side surface of the second portion 250_P2 of the contact via structure 250.

For example, a length of the first contact via structure 250_1 in the first direction DR1 may be equal to or substantially equal to a distance in the first direction DR1 between the third gate spacer 243 covering the first gate stack 200 and the third gate spacer 243 covering the second gate stack 200. For example, a length of the second portion 250_P2 of the first contact via structure 250_1 in the first direction DR1 may be equal or substantially equal to a distance in the first direction DR1 between the third gate spacer 243 covering the first gate stack 200 and the third gate spacer 243 covering the second gate stack 200.

However, in the case of the second contact via structures 250_2, since a first side surface in the first direction DR1 is in contact with the third gate spacer 243, but a second side surface in the first direction DR1 is in contact with the first interlayer insulating film 207, in order to prevent the second contact via structures 250_2 from having an enlarged profile or voids, each of the second contact via structures 250_2 may include a first contact insulating film 252.

For example, the second contact via structure 250_2 may include a gate contact via 251 extending in a third direction DR3 from the second active region A2 to the core circuit wiring 510, a first contact insulating film 252 covering a portion of a side surface of the gate contact via 251 and exposing the remaining portion of the side surface, and a second contact insulating film 253 covering a portion of the side surface of the first contact insulating film 252 and exposing the remaining portion of the side surface and exposing the remaining portion of the side surface of the gate contact via 251.

FIGS. 7 to 13 are drawings for explaining a method for manufacturing a semiconductor device according to an embodiment.

Referring to FIG. 7, a trench for separating a plurality of elements is formed in a substrate 100, and a second device isolation film 101b is formed to fill the inside of the trench. The second active region A2 may be defined by a second device isolation film 101b. Impurity regions 201 may be formed on the upper portion of the second active region A2. Impurity regions 201 may be formed by injecting p-type impurities or n-type impurities.

The gate insulating film 210, the work function control layer 225, the first conductive layer 221, the second conductive layer 222, the third conductive layer 223, and the gate capping pattern 230 are sequentially formed on the second active region A2, and these are patterned to form a gate stack 200.

By depositing an insulating material on a gate stack 200 and then performing an etching process, a gate spacer structure 240 including a first gate spacer 241, a second gate spacer 242, a third gate spacer 243, and a fourth gate spacer 244 is formed.

A first interlayer insulating film 207 is formed to fill the space between gate spacer structures 240 on a substrate 100, and a second interlayer insulating film 209 is formed on the first interlayer insulating film 207.

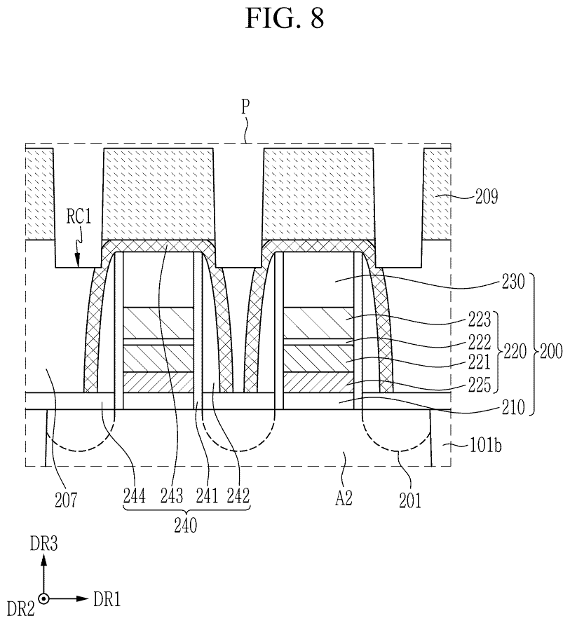

Referring to FIG. 8, a first partial etch is performed to form a first recess RC1.

For example, a mask pattern (not shown) located on the second interlayer insulating film 209 may be used to etch the second interlayer insulating film 209 and the first interlayer insulating film 207 to form a first recess RC1. The first partial etch may utilize dry etch.

The first partial etch may etch for a certain period of time and then stop (time etch), or may stop when the third gate spacer 243 is encountered or after the third gate spacer 243 is partially etched.

After the first partial etch, the mask pattern (not shown) used in the first partial etch may be removed, but is not limited thereto.

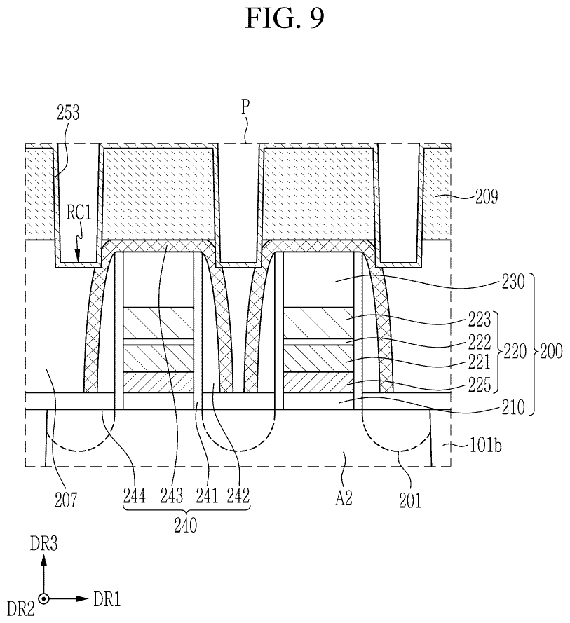

Referring to FIG. 9, a second contact insulating film 253 is formed within the first recess RC1.

For example, the second contact insulating film 253 may be formed by conformally applying an insulating material within the first recess RC1. For example, the second contact insulating film 253 may be formed using at least one of physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD) techniques, but is not limited thereto.

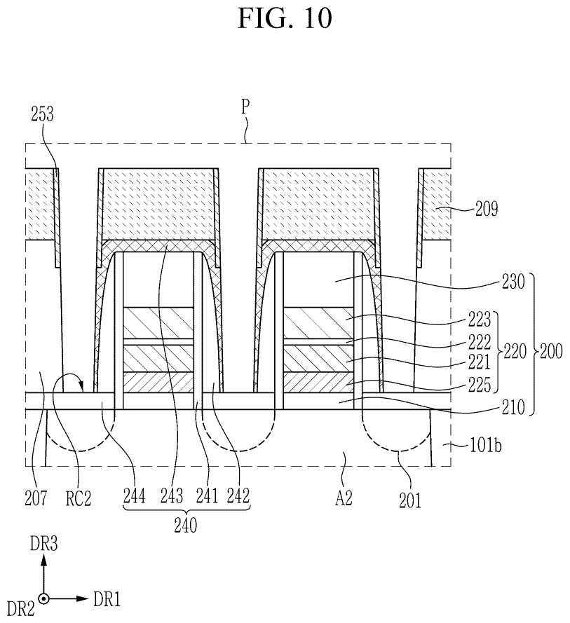

Referring to FIG. 10, a second partial etch is performed to form a second recess RC2.

For example, the second contact insulating film 253 located within the first recess RC1 may be used as a mask pattern to etch the first interlayer insulating film 207 to form the second recess RC2. The second partial etch may utilize dry etch.

The second partial etch may be stopped when it encounters the fourth gate spacer 244. Through this, even if the mask pattern used for the first partial etch is removed after the first partial etch, the loss of the second interlayer insulating film 209 may be minimized during the second partial etch.

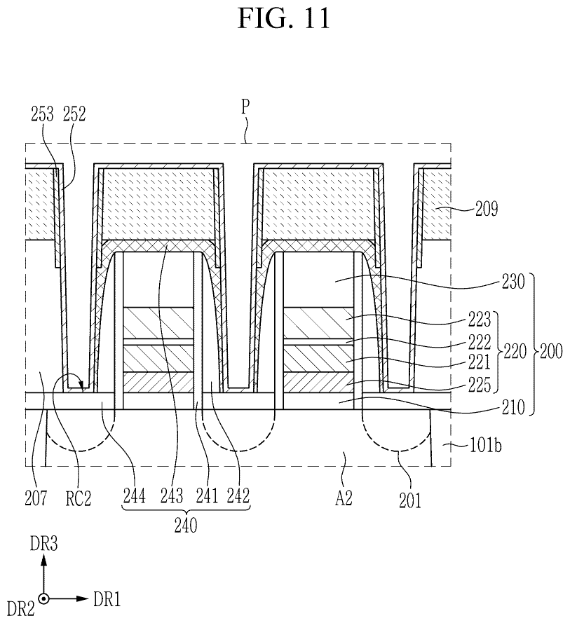

Referring to FIG. 11, a first contact insulating film 252 is formed within the second recess RC2.

For example, the first contact insulating film 252 may be formed by conformally applying an insulating material within the second recess RC2. For example, the first contact insulating film 252 may be formed using at least one of physical vapor deposition (PVD), thermal chemical vapor deposition (thermal CVD), low-pressure chemical vapor deposition (LP-CVD), plasma-enhanced chemical vapor deposition (PE-CVD), or atomic layer deposition (ALD) techniques, but is not limited thereto.

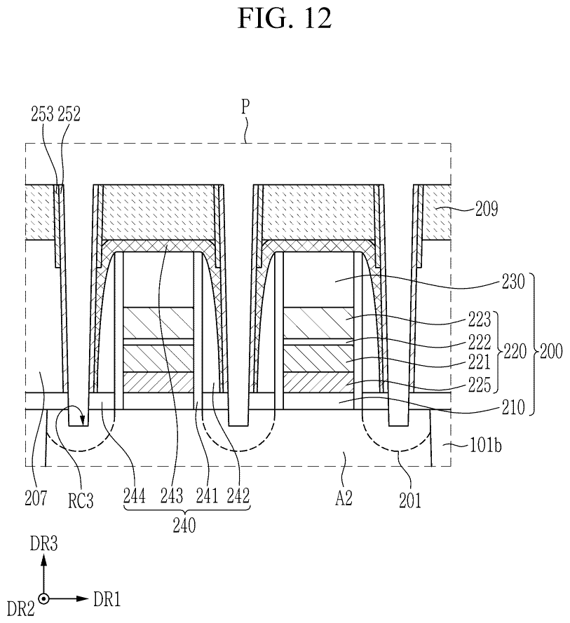

Referring to FIG. 12, a third partial etch is performed to form a third recess RC3.

For example, the first contact insulating film 252 located within the second recess RC2 may be used as a mask pattern to etch the fourth gate spacer 244 and the second active region A2 to form the third recess RC3. The third recess RC3 may penetrate the fourth gate spacer 244 and the upper surface of the second active region A2 to a certain depth from the upper surface of the second active region A2. The third partial etch may utilize dry etch.

The third partial etch may stop when the second active region A2 is encountered or after the second active region A2 is etched to some depth from the upper surface. Through this, even if the mask pattern used for the first partial etch is removed after the first partial etch, the loss of the second interlayer insulating film 209 may be minimized during the third partial etch.

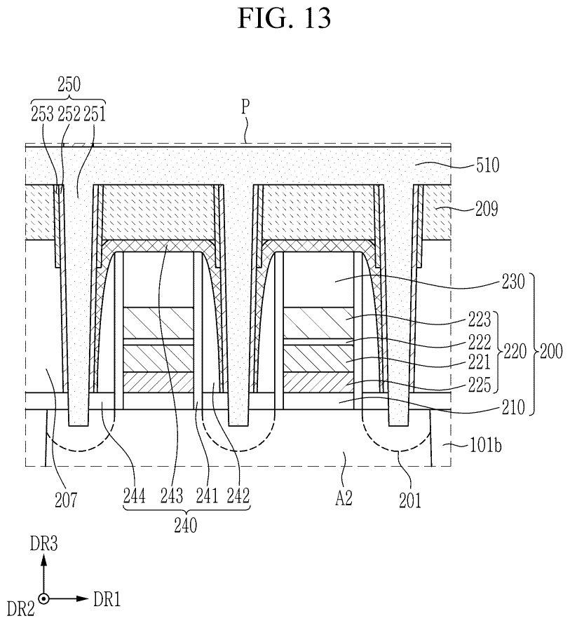

Referring to FIG. 13, a gate contact via 251 is formed within the third recess RC3.

For example, after cleaning, metal may be filled into the third recess RC3 and a planarization process may be performed to form a gate contact via 251 and a core circuit wiring 510 on the gate contact via 251. For example, the planarization process may include a chemical mechanical polishing (CMP) process, but is not limited thereto and may be varied.

In this way, by forming a contact via structure 250 through a process of performing a first partial etch, forming a second contact insulating film 253, performing a second partial etch, forming a first contact insulating film 252, performing a third partial etch, and forming a gate contact via 251, the third recess RC3 does not have an enlarged profile, thereby preventing voids from being generated during the process of cleaning or filling metal into the third recess RC3.

While this disclosure has been described in connection with what is presently considered to be practical embodiments, it is to be understood that the inventive concept is not limited to the disclosed embodiments, but, on the contrary, is intended to cover various modifications and equivalent arrangements included within the spirit and scope of the appended claims.

What is claimed is:

1. A semiconductor device, comprising:
a substrate having an active region formed thereon;
a gate stack on the active region;
a circuit wiring disposed above the gate stack; and
a contact via structure located on a side surface of the gate stack in a first direction parallel to an upper surface of the active region and located between the active region and the circuit wiring,
wherein the contact via structure includes:
a gate contact via extending in a third direction perpendicular to the upper surface of the active region between the circuit wiring and the active region;
a first contact insulating film covering a portion of the side surface of the gate contact via and exposing a remaining portion of the side surface of the gate contact via; and
a second contact insulating film covering a portion of a side surface of the first contact insulating film and exposing a remaining portion of the side surface of the first contact insulating film, and exposing a remaining portion of the side surface of the gate contact via.

2. The semiconductor device of claim 1, wherein the contact via structure has:
a first portion connected to the circuit wiring and including the gate contact via, the first contact insulating film, and the second contact insulating film;
a second portion connected to the active region and including the gate contact via; and
a third portion located between the first portion and the second portion and including the gate contact via and the first contact insulating film,
wherein the second contact insulating film does not extend into the second portion or the third portion, and the first contact insulating film does not extend into the second portion.

3. The semiconductor device of claim 2, wherein in the first portion of the contact via structure:
the first contact insulating film covers a side surface of the gate contact via; and
the second contact insulating film covers a side surface of the first contact insulating film.

4. The semiconductor device of claim 2, wherein in the third portion of the contact via structure:
the first contact insulating film covers the side surface of the gate contact via; and
the second contact insulating film does not cover the side surface of the first contact insulating film.

5. The semiconductor device of claim 2, wherein in the second portion of the contact via structure:
the first contact insulating film does not cover the side surface of the gate contact via;
the second contact insulating film does not cover the side surface of the first contact insulating film; and
the gate contact via is exposed.

6. The semiconductor device of claim 2, wherein the second portion of the contact via structure penetrates the upper surface of the active region into the active region, and is in a contact with the active region.

7. The semiconductor device of claim 2, wherein the semiconductor device further includes:
a gate spacer located on the active region next to the gate stack in the first direction; and
an interlayer insulating film located on the gate spacer and covering the gate stack.

8. The semiconductor device of claim 7, wherein the first portion of the contact via structure penetrates through the gate spacer and the upper surface of the active region into the active region.

9. The semiconductor device of claim 7, wherein the first contact insulating film extends in the third direction from the gate spacer to a lower surface of the circuit wiring.

10. The semiconductor device of claim 7, wherein the gate spacer is a gate spacer structure, and the gate spacer structure includes:
a first gate spacer on the side surface of the gate stack in the first direction;
a second gate spacer on the side surface of the first gate spacer in the first direction;
a third gate spacer covering the first gate spacer and the second gate spacer; and
a fourth gate spacer under the second gate spacer and the third gate spacer.

11. The semiconductor device of claim 10, wherein:
the first contact insulating film is in contact with a first portion of the side surface of the third gate spacer in the first direction;
the second contact insulating film is in contact with a second portion of the side surface of the third gate spacer in the first direction; and
the second contact insulating film is in contact with a portion of the side surface of the interlayer insulating film on the third gate spacer in the first direction.

12. The semiconductor device of claim 11, wherein the second contact insulating film extends in the third direction from the side surface of the third gate spacer in the first direction to a lower surface of the circuit wiring.

13. The semiconductor device of claim 10, wherein the gate stack is a first gate stack, and the semiconductor device includes:
a second gate stack spaced apart from the first gate stack in the first direction;
a first contact via structure between the first gate stack and the second gate stack; and
second contact via structures respectively located on an outer side of the first gate stack and the second gate stack in the first direction.

14. The semiconductor device of claim 13, wherein the third portion of the first contact via structure is interposed between the third gate spacer covering the first gate stack and the third gate spacer covering the second gate stack.

15. The semiconductor device of claim 13, wherein the third portion of the second contact via structure is interposed between the third gate spacer covering the first gate stack or the second gate stack and the interlayer insulating film.

16. A semiconductor device, comprising:
a substrate having an active region formed thereon;
a gate stack on the active region;
a circuit wiring disposed above the gate stack; and
a contact via structure located on a side surface of the gate stack in a first direction parallel to an upper surface of the active region and located between the active region and the circuit wiring,
wherein the contact via structure has:
a first portion connected to the circuit wiring;
a second portion connected to the active region; and
a third portion between the first portion and the second portion,
wherein a length of the contact via structure in the first direction has a step between the first portion and the third portion, and has a step between the third portion and the second portion.

17. The semiconductor device of claim 16, wherein a length of a lower end of the first portion in the first direction is greater than a length of an upper end of the third portion in the first direction.

18. The semiconductor device of claim 16, wherein a length of a lower end of the third portion in the first direction is greater than a length of an upper end of the second portion in the first direction.

19. The semiconductor device of claim 16, wherein:
the third portion is located on the second portion;
the first portion is located on the third portion; and
the second portion, the third portion, and the first portion are sequentially stacked in a third direction perpendicular to the upper surface of the active region.

20. A semiconductor device, comprising:
a substrate having an active region formed thereon;
a circuit wiring formed on the substrate;
a first gate stack and a second gate stack located on the active region and spaced apart from each other in a first direction parallel to an upper surface of the active region;
a first contact via structure located between the first gate stack and the second gate stack and between the active region and the circuit wiring; and
second contact via structures, each located on an outer side of either the first gate stack or the second gate stack in the first direction and located between the active region and the circuit wiring,
wherein:
the first contact via structure includes a gate contact via extending in a third direction perpendicular to an upper surface of the active region from the active region to the circuit wiring, and a first contact insulating film located on a side surface of the gate contact via; and
the second contact via structure includes a gate contact via extending in the third direction from the active region to the circuit wiring, a first contact insulating film covering a portion of a side surface of the gate contact via and exposing a remaining portion of the side surface of the gate contact via, and a second contact insulating film covering a portion of the side surface of the first contact insulating film and exposing a remaining portion of the side surface of the first contact insulating film, and exposing the remaining portion of the side surface of the gate contact via.
